(19) United States
(12) Patent Application Publication
(10) Pub. No.: US 2024/0146179 A1
(43) Pub. Date: May 2, 2024

(54) DRIVING DEVICE FOR SEMICONDUCTOR ELEMENT, AND POWER CONVERSION DEVICE

(71) Applicant: Mitsubishi Electric Corporation, Tokyo (JP)

(72) Inventors: Koki OCHI, Chiyoda-ku, Tokyo (JP); Chihiro KAWAHARA, Chiyoda-ku, Tokyo (JP)

(73) Assignee: Mitsubishi Electric Corporation, Tokyo (JP)

(21) Appl. No.: 18/278,181

(22) PCT Filed: Mar. 24, 2021
(86) PCT No.: PCT/JP2021/012233

§ 371 Date: Aug. 22, 2023

(51) Int. Cl. H02M 1/088; H02M 1/00; H02M 1/32

(52) U.S. Cl. CPC H02M 1/088; H02M 1/0009; H02M 1/327

(57) ABSTRACT

A driving signal generation unit outputs one of an ON gate voltage for turning on a semiconductor element and an OFF gate voltage for turning off to a gate. A gate threshold voltage estimation unit calculates an estimation value of a gate threshold voltage of the semiconductor element, based on state information of the semiconductor element acquired when the semiconductor element is in an OFF state and in a reverse conducting state in which a reverse conducting element is energized.

### TECHNICAL FIELD

The present disclosure relates to a driving device for a semiconductor element, and a power conversion device.

### BACKGROUND ART

In transistors having insulated gate structures, such as metal-oxide-semiconductor field-effect transistors (MOSFETs) and insulated gate bipolar transistors (IGBTs), gate threshold voltage is known to vary due to temperature change, deterioration of insulating oxide films, and the like.

Silicon carbide (SiC) semiconductor elements, which have been increasingly applied in recent years, can achieve high withstand voltage, low loss, fast switching, and high temperature operation, but the gate threshold voltage tends to vary because the quality of oxide films is lower than that of silicon (Si) semiconductor elements. Furthermore, SiC semiconductor elements exhibit a phenomenon in which the gate threshold voltage varies for a very short time depending on the history of gate voltage application.

If the gate threshold voltage of the semiconductor element varies because of the factors as described above, the power loss or switching timing of the semiconductor element changes, which may cause unintended temperature increase, false turn-on, and the like.

For this, there is a demand for technology for detecting the gate threshold voltage of semiconductor elements in real time. For example, WO 2019/058545 (PTL 1) describes a switching element control circuit capable of calculating a gate threshold voltage from detection values of operating temperature and current of a semiconductor element. As a result, even when the gate threshold voltage deviates from an initial value, the value can be calculated.

### CITATION LIST

### Patent Literature

PTL 1: WO 2019/058545

### SUMMARY OF INVENTION

### Technical Problem

In the switching element control circuit described in PTL 1, change from an initial state of gate threshold voltage is estimated from drain current and operating temperature in the ON state of the transistor.

However, since change of electrical resistance in the semiconductor element is small in the ON region in which the gate-to-source voltage is large, change of drain current relative to the gate threshold voltage is not so large. In other words, the dependency of gate threshold voltage is relatively small in the drain current characteristic of the transistor in the ON state and this may reduce the accuracy in estimating the gate threshold voltage based on the characteristic.

The present disclosure is made in order to solve such a problem and an object of the present disclosure is to accurately detect change of gate threshold voltage of a semiconductor element having an insulated gate structure.

### Solution to Problem

According to an aspect of the present disclosure, a driving device for a semiconductor element having an insulated gate structure is provided. The semiconductor element is configured such that current is produced from a first electrode to a second electrode in an ON state, and contains a reverse conducting element for ensuring a current path from the second electrode to the first electrode. The driving device includes a driving signal generation unit and a gate threshold voltage estimation unit. The driving signal generation unit outputs one of an ON gate voltage for turning on the semiconductor element and an OFF gate voltage for turning off the semiconductor element to a gate of the semiconductor element. The gate threshold voltage estimation unit calculates an estimation value of a gate threshold voltage of the semiconductor element, based on state information of the semiconductor element acquired when the semiconductor element is in an OFF state and in a reverse conducting state in which the reverse conducting element is energized.

According to another aspect of the present disclosure, a power conversion device is provided. The power conversion device includes a main conversion unit and a control unit. The main conversion unit includes at least one semiconductor element controlled on/off by the driving device for a semiconductor element described above, and converts an input power and outputs the converted. The control unit outputs a control signal for controlling the main conversion unit to the main conversion unit.

### Advantageous Effects of Invention

According to the present disclosure, change of the gate threshold voltage can be detected with high accuracy by calculating an estimation value of the gate threshold voltage, from state information when the semiconductor element is in the OFF state and the reverse conducting state, in which the gate threshold voltage dependency of the element characteristic is large.

### BRIEF DESCRIPTION OF DRAWINGS

FIG. 1 is a block diagram illustrating a configuration of a driving device for a semiconductor element according to a first embodiment.

FIG. 2 is a block diagram illustrating a hardware configuration example of a gate threshold voltage estimation unit.

FIG. 3 is a conceptual diagram illustrating an example of correspondence information stored in a retention unit shown in FIG. 1.

FIG. 4 is a block diagram illustrating a configuration example of a reverse conducting element state detection unit according to the first embodiment.

FIG. 5 is a waveform diagram illustrating an operation example of the driving device for a semiconductor element according to the first embodiment.

FIG. 6 is a block diagram illustrating a configuration of a driving device for a semiconductor element according to a second embodiment.

FIG. 7 is a block diagram illustrating a configuration example of a reverse conducting element state detection unit according to the second embodiment.

FIG. 8 is a waveform diagram illustrating an operation example of the driving device for a semiconductor element according to the second embodiment.

FIG. 9 is a block diagram illustrating a configuration example of a reverse conducting element state detection unit according to a third embodiment.

FIG. 10 is a waveform diagram illustrating an operation example of a driving device for a semiconductor element according to the third embodiment.

FIG. 11 is a block diagram illustrating a configuration example of a reverse conducting element state detection unit according to a modification of the third embodiment.

FIG. 12 is a waveform diagram illustrating an operation example of a driving device for a semiconductor element according to a modification of the third embodiment.

FIG. 13 is a flowchart illustrating the operation of a driving device for a semiconductor element according to a fourth embodiment.

FIG. 14 is a block diagram illustrating a configuration example of a driving signal generation unit according to the fourth embodiment.

FIG. 15 is a block diagram illustrating a configuration of a driving device for a semiconductor element according to a fifth embodiment.

FIG. 16 is a flowchart illustrating the operation of the driving device for a semiconductor element according to the fifth embodiment.

FIG. 17 is a flowchart illustrating a modification of the operation of the driving device for a semiconductor element according to the fifth embodiment.

FIG. 18 is a block diagram showing a configuration of a power conversion system to which a power conversion device is applied according to a sixth embodiment.

### DESCRIPTION OF EMBODIMENTS

Embodiments of the present disclosure will be described in detail below with reference to the drawings. In the following, the same or corresponding parts in the drawings are denoted by the same reference signs and a description thereof is basically not repeated.

### First Embodiment

As shown in FIG. 1, a driving device 100a for a semiconductor element according to a first embodiment is connected to a semiconductor element TR having an insulated gate structure which is a gate threshold voltage detection target.

In the example in FIG. 1, semiconductor element TR is a MOSFET containing a body diode BD as a “reverse conducting element”. Semiconductor element TR has a drain D that is “first electrode”, a source S that is “second electrode”, and a gate G. Hereinafter the voltage of gate G with respect to source S is denoted as “gate-to-source voltage Vgs”, current flowing between drain D and source S is denoted as “drain-to-source current Ids”, and voltage of drain D with respect to source S is denoted as “drain-to-source voltage Vds”.

In other words, gate-to-source voltage Vgs corresponds to an example of “first voltage” that is a voltage difference of the gate with respect to the second electrode, and drain-to-source voltage Vds corresponds to an example of “second voltage” that is a voltage difference of the first electrode with respect to the second electrode. Drain-to-source current Ids corresponds to an example of “first current” flowing between the first and second electrodes. As for drain-to-source current Ids, the direction of current flowing from drain D to source S is defined as positive (Ids>0) and the direction of current flowing from source S to drain D is defined as negative (Ids<0).

Driving device 100a includes a gate threshold voltage estimation unit 10a and a driving signal generation unit 20. Driving signal generation unit 20 turns on/off semiconductor element TR by driving the voltage of gate G of semiconductor element TR. For example, driving signal generation unit 20 controls the on/off of semiconductor element TR by applying an ON gate voltage Vgon or an OFF gate voltage Vgoff to gate G in accordance with a gate signal Sg for controlling the on/off of semiconductor element TR. ON gate voltage Vgon is set to a voltage sufficiently higher than gate threshold voltage Vth. OFF gate voltage Vgoff is set to, for example, −5 [V], in order to prevent false turn-on.

Hereinafter, the OFF state of semiconductor element TR is defined as a state in which gate-to-source voltage Vgs is lower than gate threshold voltage Vth of semiconductor element TR (Vgs<Vth).

Gate threshold voltage estimation unit 10a includes a state detection unit 3, a reverse conducting element state detection unit 4a, a retention unit 5, and a gate threshold voltage reference unit 6.

Gate threshold voltage estimation unit 10a and driving signal generation unit 20 may be fabricated separately or may be formed in one module. Furthermore, semiconductor element TR may be further integrated to make an intelligent power module (IPM).

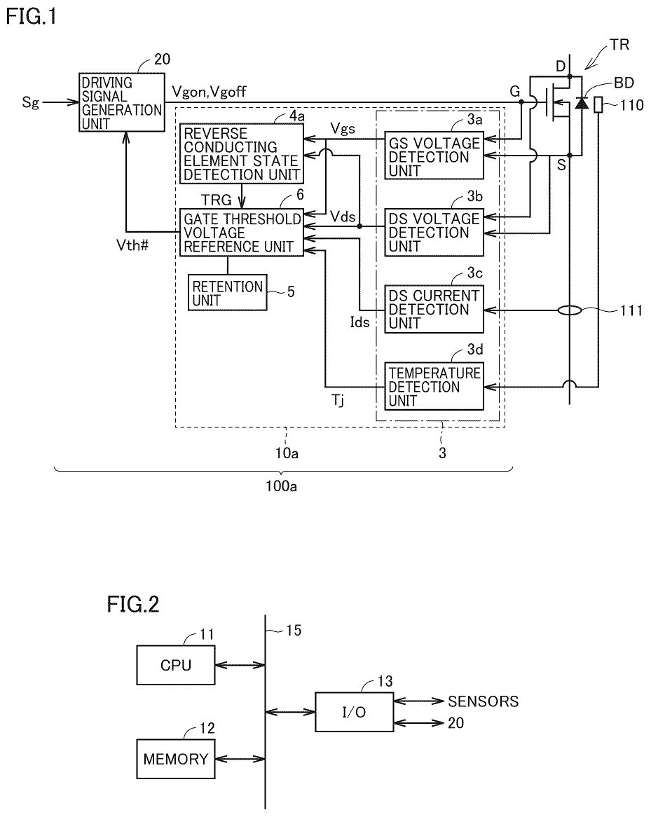

FIG. 2 shows a hardware configuration example of the gate threshold voltage estimation unit 10a. For example, gate threshold voltage estimation unit 10a can be configured with, for example, a microcomputer receiving a sensor detection value.

The microcomputer includes a central processing unit (CPU) 11, a memory 12, and an input/output (I/O) interface 13. CPU 11, memory 12, and I/O interface 13 can mutually exchange data via a bus 15. A program is stored in advance in a partial area of memory 12. CPU 11 executes the program to implement the functions of state detection unit 3, reverse conducting element state detection unit 4, retention unit 5, and gate threshold voltage reference unit 6 shown in FIG. 1. I/O interface 13 receives and outputs signals and data from/to the outside of the microcomputer (for example, driving signal generation unit 20 and not-shown sensors).

Alternatively, unlike the example in FIG. 2, at least a part of gate threshold voltage estimation unit 10a may be configured with a circuit such as a field programmable gate array (FPGA) or an application specific integrated circuit (ASIC). Alternatively, at least a part of gate threshold voltage estimation unit 10a may be configured with an analog circuit.

In this way, the functions of state detection unit 3, reverse conducting element state detection unit 4, retention unit 5, and gate threshold voltage reference unit 6 shown in FIG. 1 can be implemented by at least one of software processing and hardware processing.

Returning to FIG. 1, state detection unit 3 includes a GS voltage detection unit 3a to detect gate-to-source voltage Vgs, a DS voltage detection unit 3b to detect drain-to-source voltage Vds, a DS current detection unit 3c to detect drain-to-source current Ids, and a temperature detection unit 3d to detect the temperature of semiconductor element TR (hereinafter referred to as operating temperature Tj).

GS voltage detection unit 3a calculates gate-to-source voltage Vgs from a voltage sampling value of gate G and a sampling value of source S. DS voltage detection unit 3b calculates drain-to-source voltage Vds from a voltage sampling value of drain D and a sampling value of source S. Alternatively, GS voltage detection unit 3a and DS voltage detection unit 3b may be configured to sample a detection value of a voltage sensor (not shown) that detects gate-to-source voltage Vgs and drain-to-source voltage Vds.

DS current detection unit 3c detects drain-to-source current Ids based on an output value of a current detector 111. For example, a shunt resistor and a current transformer can be used for current detector 111. Temperature detection unit 3d detects operating temperature Tj, based on an output value of temperature detector 110. For example, a diode for temperature detection contained in semiconductor element TR and a thermistor element arranged in the vicinity of semiconductor element TR can be employed for temperature detector 110.

Gate-to-source voltage Vgs, drain-to-source voltage Vds, drain-to-source current Ids, and operating temperature Tj detected by state detection unit 3 are input to gate threshold voltage reference unit 6. In other words, gate-to-source voltage Vgs, drain-to-source voltage Vds, drain-to-source current Ids, and operating temperature Tj correspond to an example of “state information of the semiconductor element”.

Any method can be employed as the method of detecting voltage, current, and temperature by state detection unit 3 as long as the accuracy (resolution) necessary for gate threshold voltage estimation described later can be ensured.

Reverse conducting element state detection unit 4 outputs a trigger signal TRG when detecting that semiconductor element TR is in the OFF state and the reverse conducting state, based on a detection value by state detection unit 3. Specifically, when it is detected that semiconductor element TR is in the OFF state and in the reverse conducting state in which body diode BD (reverse conducting element) is in the energized state, trigger signal TRG is output. Trigger signal TRG is input to gate threshold voltage reference unit 6.

Retention unit 5 stores correspondence information of gate-to-source voltage Vgs, drain-to-source voltage Vds, drain-to-source current Ids, and operating temperature Tj with gate threshold voltage Vth in the OFF state and the reverse conducting state of semiconductor element TR.

For example, retention unit 5 can retain the correspondence information in a lookup table format in which gate threshold voltage Vth is associated with a combination of state values such as gate-to-source voltage Vgs, drain-to-source voltage Vds, drain-to-source current Ids, and operating temperature Tj. Alternatively, retention unit 5 may retain the correspondence information in a fitting function format that represents the dependency of state values (gate-to-source voltage Vgs, drain-to-source voltage Vds, drain-to-source current Ids, and operating temperature Tj) on gate threshold voltage Vth.

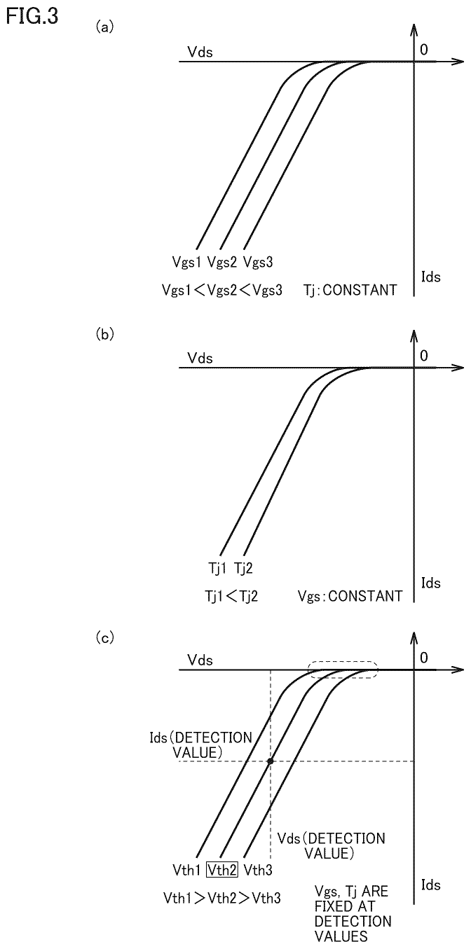

FIG. 3 shows a conceptual diagram illustrating an example of the correspondence information of semiconductor element TR that is stored in retention unit 5. FIGS. 3(a) to (c) show the Ids-Vds characteristic (current-voltage characteristic) when semiconductor element TR is in the OFF state and the reverse conducting state. Thus, in the Ids-Vds characteristic shown in FIGS. 3(a) to (c), Vds<0 and Ids<0.

FIG. 3(a) shows the Ids-Vds characteristic under different Vgs, under constant gate threshold voltage Vth and operating temperature Tj. As shown in FIG. 3(a), the Ids-Vds characteristic has gate-to-source voltage Vgs dependency in which drain-to-source voltage Vds increases as gate-to-source voltage Vgs increases.

FIG. 3(b) shows Ids-Vds under different operating temperatures Tj, under constant gate threshold voltage Vth and gate-to-source voltage Vgs. As shown in FIG. 3(b), the Ids-Vds characteristic has operating temperature Tj dependency such that drain-to-source voltage Vds increases as operating temperature Tj increases.

The Ids-Vds characteristic in FIGS. 3(a) and (b) can be acquired, for example, in a characteristic test of semiconductor element TR. Since the current-voltage characteristic (Ids-Vds characteristic) of a transistor (semiconductor element TR) is determined by the difference between gate-to-source voltage Vgs and gate threshold voltage Vth (Vds-Vth) and operating temperature Tj, change of current-voltage characteristic (Ids-Vds) with gate threshold voltage Vth changing can be equivalently obtained from change of Ids-Vds characteristic with Vgs swinging.

Therefore, the gate threshold voltage Vth dependency of the Ids-Vds characteristic under constant gate-to-source voltage Vgs and operating temperature Tj as shown in FIG. 3(c) can be obtained from the Vgs dependency in FIG. 3(a) and the Tj dependency in FIG. 3(b) obtained by the characteristic test.

In the conducting state of the reverse conducting element (body diode BD), Vds (absolute value) increases as Ids (absolute value) increases from an operating point (Ids=0) at the ON timing at which the reverse conducting element turns from the non-conducting state to the conducting state, as surrounded by the dotted line in FIG. 3(c), along the Ids-Vds characteristic line in accordance with gate threshold voltage Vth at the point of time.

In this way, the Ids-Vds characteristic in the OFF state and the reverse conducting state of semiconductor element TR has dependency on gate-to-source voltage Vgs, operating temperature Tj, and gate threshold voltage Vth. In other words, gate threshold voltage Vth in the OFF state and the reverse conducting state of semiconductor element TR can be uniquely estimated from gate-to-source voltage Vgs, drain-to-source voltage Vds, drain-to-source current Ids, and operating temperature Tj.

For example, a gate threshold voltage estimation value of semiconductor element TR at a certain timing can be obtained by extracting an Ids-Vds characteristic line having a combination of detection values of drain-to-source current Ids and drain-to-source voltage Vds at the timing, from a plurality of Ids-Vds characteristic lines with different gate threshold voltages Vth shown in FIG. 3(c) under fixed gate-to-source voltage Vgs and operating temperature Tj detected at the timing.

In other words, it can be understood that the Ids-Vds characteristic for each gate threshold voltage as shown in FIG. 3(c) is prepared for the combinations of operating temperature Tj and gate-to-source voltage Vgs, whereby consequently, a lookup table or a fitting function can be created in advance, in which gate threshold voltage Vth is associated with a combination of gate-to-source voltage Vgs, drain-to-source voltage Vds, drain-to-source current Ids, and operating temperature Tj at a certain timing. These lookup table and fitting function correspond to an example of “correspondence information stored in the retention unit”.

The Vgs dependency of the Ids-Vds characteristic in the reverse conducting state of semiconductor element TR is greater in the OFF state of semiconductor element TR than in the ON state of semiconductor element TR. Similarly, the degree of the Vgs dependency of the Ids-Vds characteristic has a positive correlation to the degree of the gate threshold voltage Vth dependency. Thus, the Vth dependency of the current-voltage characteristic in the reverse conducting state of semiconductor element TR is also greater in the OFF state of semiconductor element TR than in the ON state of semiconductor element TR. In the present embodiment, therefore, gate threshold voltage Vth is estimated when semiconductor element TR is in the OFF state and the reverse conducting state, thereby achieving higher accuracy.

In the estimation using the Ids-Vds characteristic that changes depending on gate threshold voltage Vth illustrated in FIG. 3, gate threshold voltage Vth can be estimated with high accuracy even when gate threshold voltage Vth changes due to deterioration of insulating oxide films or gate voltage application history. Unlike PTL 1, the accuracy in estimating gate threshold voltage Vth can be increased by using the Ids-Vds characteristic in the OFF state and the reverse conducting state with large Vth dependency.

However, when gate-to-source voltage Vgs of semiconductor element TR is too large in the negative direction, the Vgs dependency and the Vth dependency in the Ids-Vds characteristic at the time of reverse conduction may disappear. It is therefore necessary to set OFF gate voltage Vgoff output by driving signal generation unit 20 to a value to such a degree that the above dependency does not disappear. For example, it is desirable that OFF gate voltage Vgoff is set to a value as high as possible in a range that can prevent occurrence of false turn-on due to external noise.

Insulated gate-type SiC transistors such as SiC-MOSFETs are known as semiconductor elements having the current-voltage characteristic (Ids-Vds characteristic) involving the dependency as described above, and the gate threshold voltage estimation according to the present embodiment can be applied to semiconductor elements having similar characteristics.

Returning to FIG. 1, at a timing when trigger signal TRG changes from “0” to “1”, that is, at a timing when semiconductor element TR changes into a state that is the OFF state and the reverse conducting state from a state that is not these states, gate threshold voltage reference unit 6 reads, from state detection unit 3, the state information (specifically, gate-to-source voltage Vgs, drain-to-source voltage Vds, drain-to-source current Ids, and operating temperature Tj) of semiconductor element TR at that timing. Further, the correspondence information stored in retention unit 5 is referred to using the read state information of semiconductor element TR to calculate a gate threshold voltage estimation value Vth # at that timing. The calculated gate threshold voltage estimation value Vth # can be output to driving signal generation unit 20.

For example, when retention unit 5 retains the correspondence information in a lookup table format, gate threshold voltage reference unit 6 selects a set of parameters closest to a combination of detection values of the state information of semiconductor element TR by state detection unit 3 and sets a reference value associated with the combination as gate threshold voltage estimation value Vth #.

Alternatively, when retention unit 5 retains the characteristic information in a fitting function format, gate threshold voltage reference unit 6 can calculate gate threshold voltage estimation value Vth # from the detection values of the state information of semiconductor element TR by state detection unit 3 and information of the fitting function.

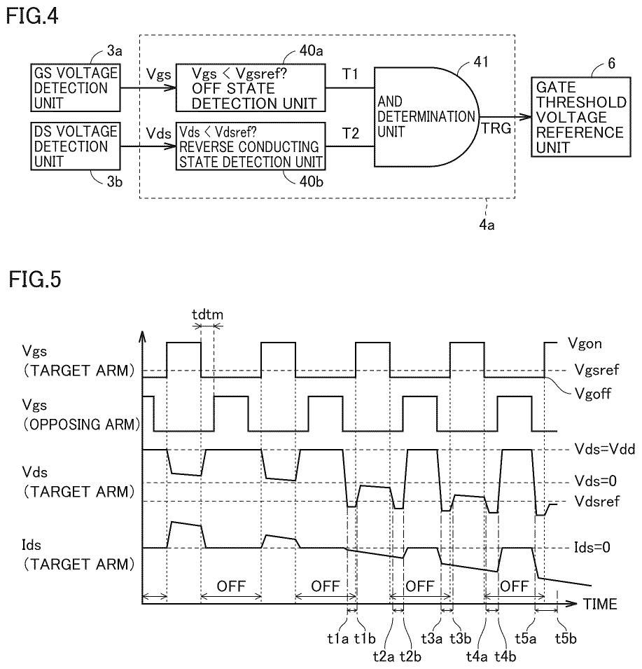

FIG. 4 shows a block diagram illustrating a configuration example of reverse conducting element state detection unit 4a according to the first embodiment.

Reverse conducting element state detection unit 4a includes an OFF state detection unit 40a, a reverse conducting state detection unit 40b, and an AND determination unit 41. OFF state detection unit 40a compares gate-to-source voltage Vgs detected by GS voltage detection unit 3a with an OFF determination voltage Vgsref and outputs a signal T1. When Vgs<Vgsref, OFF state detection unit 40a determines that semiconductor element TR is in the OFF state and sets T1=“1”. When not Vgs<Vgsref, it is not determined that semiconductor element TR is in the OFF state, and T1=“0” is set. OFF determination voltage Vgsref corresponds to an example of “first determination voltage”.

OFF determination voltage Vgsref can be set to satisfy Vgsoff<Vgsref<Vthmin for the minimum value Vthmin of gate threshold voltage in a variable range of semiconductor element TR, and gate-to-source voltage Vgsoff with OFF gate voltage Vgoff being output from driving signal generation unit 20. The above minimum value Vthmin, which changes with the structure and manufacturing process of the semiconductor element, can be predetermined using statistical techniques or the like.

Reverse conducting state detection unit 40b compares drain-to-source voltage Vds detected by DS voltage detection unit 3b with a reverse conduction determination voltage Vdsref set to a negative value and outputs a signal T2. When Vds<Vdsref, reverse conducting state detection unit 40b determines that semiconductor element TR is in the reverse conducting state and sets T2=“1”. When not Vds<Vdsref, it is determined that semiconductor element TR is not in the reverse conducting state, and T2=“0” is set. Reverse conduction determination voltage Vdsref corresponds to an example of “second determination voltage”.

AND determination unit 41 outputs the result of AND operation of signal T1 from OFF state detection unit 40a and signal T2 from reverse conducting state detection unit 40b, as trigger signal TRG shown in FIG. 1. Trigger signal TRG therefore is set to “1” in a period in which it is simultaneously detected that semiconductor element TR is in the OFF state and in the reverse conducting state, and is set to “0” in the other period.

In the configuration example in FIG. 4, OFF state detection unit 40a and reverse conducting state detection unit 40b can be configured with analog or digital comparators but may be configured with other circuits that can achieve the same functions. AND determination unit 41 can also be configured with an analog or digital logic operation circuit or other circuits that can achieve the same functions.

Reverse conduction determination voltage Vdsref may be set to a negative value as described above, but it is preferable that it is set to satisfy Vdsref<Vdsknee for a rising voltage Vdsknee of the body diode (Vdsknee<0). In this way, it is possible to suppress reduction of estimation accuracy due to the estimation of the gate threshold voltage using the state quantity of semiconductor element TR (detection values by state detection unit 3) in a region in which gate threshold voltage Vth dependency is small, such as Vdsknee<Vds<0.

Further, reverse conduction determination voltage Vdsref is normally set to Vdsref<0, but it is preferable that it is set such that a region in which gate threshold voltage Vth dependency is small is avoided. In other words, it is preferable that reverse conduction determination voltage Vdsref is set to a maximum value (voltage close to 0) in lower voltages (negative voltage region) than in the region above. With this configuration, even when reverse conduction current is small, it can be detected that semiconductor element TR is in the reverse conducting state, and gate threshold voltage Vth can be estimated with high frequency.

FIG. 5 shows a waveform diagram illustrating an operation example of the driving device for a semiconductor element according to the first embodiment.

FIG. 5 shows an example of transition of current and voltage when semiconductor element TR in FIG. 1 and another semiconductor element constitute arms, which are incorporated into a power conversion device. In FIG. 5, semiconductor element TR in FIG. 1 that is a gate threshold voltage estimation target is denoted as “target arm”, and another semiconductor element that constitutes an arm identical to semiconductor element TR is denoted as “opposing arm”.

In FIG. 5, since the semiconductor element in the opposing arm is a switching element controlled on/off, gate-to-source voltage Vgs of the target arm and the other arm is set such that the semiconductor element in the target arm and the semiconductor element in the opposing arm are turned on/off in a complementary manner with a dead time tdtm.

Drain-to-source voltage Vds during conduction of the semiconductor element is normally extremely small compared with a power supply voltage Vdd of the power conversion device, but the waveform diagrams including FIG. 5 depict the absolute value of Vds in the vicinity of 0 [V] in an enlarged manner.

Drain-to-source voltage Vds and drain-to-source current Ids of semiconductor element TR in the target arm change with the on/off of semiconductor element TR according to gate-to-source voltage Vgs. In other words, in a period of Ids≥0 that is the ON period of semiconductor element TR, Vds≥0. Conversely, in a period of Ids<0 of semiconductor element TR, Ids is also negative.

Therefore, by setting reverse conduction determination voltage Vdsref<0, reverse conducting state detection unit 40b can accurately detect when semiconductor element TR is in the reverse conducting state.

In a period in which semiconductor element TR is off, gate-to-source voltage Vgs of semiconductor element TR is less than gate threshold voltage Vth. Therefore, by setting OFF determination voltage Vgsref to satisfy Vgsoff<Vgsref<Vthmin as described above, OFF state detection unit 40a can accurately detect the OFF period of semiconductor element TR, which is denoted as “OFF” in the drawings.

In the example in FIG. 5, trigger signal TRG shown in FIG. 4 is set to “1” in each of the periods of time t1a to t1b, t2a to t2b, t3a to t3b, t4a to t4b, and t5a to t5b, in which the OFF state of semiconductor element TR and the reverse conducting state of semiconductor element TR overlap. With this configuration, it can be reliably detected when semiconductor element TR is in the OFF state and the reverse conducting state.

Gate threshold voltage reference unit 6 operating in response to trigger signal TRG calculates gate threshold voltage estimation value Vth # using the characteristic information stored in retention unit 5, based on the detection values by state detection unit 3 (gate-to-source voltage Vgs, drain-to-source voltage Vds, drain-to-source current Ids, and operating temperature Tj) at a timing when trigger signal TRG changes from “0” to “1”. With this configuration, gate threshold voltage Vth can be estimated with high accuracy, based on the current-voltage characteristic (Ids-Vds characteristic) having Vth dependency when semiconductor element TR is in the OFF state and the reverse conducting state.

As a result, with the configuration of the present first embodiment, even when gate threshold voltage Vth of the semiconductor element varies due to temperature change, gate stress history, and the like, the gate threshold voltage can be estimated in real time and with high accuracy.

FIG. 5 depicts gate-to-source voltage Vgs that defines the on/off of the semiconductor element in the opposing arm for reference, but as is clear from the foregoing description, the estimation of the gate threshold voltage according to the present embodiment does not require information on the opposing arm and can be realized only with information about semiconductor element TR that is the estimation target. Further, the semiconductor element in the opposing arm may be configured with a diode without a switching function, and also in this case, gate threshold voltage reference unit 6 can estimate gate threshold voltage Vth of semiconductor element TR similarly.

### Second Embodiment

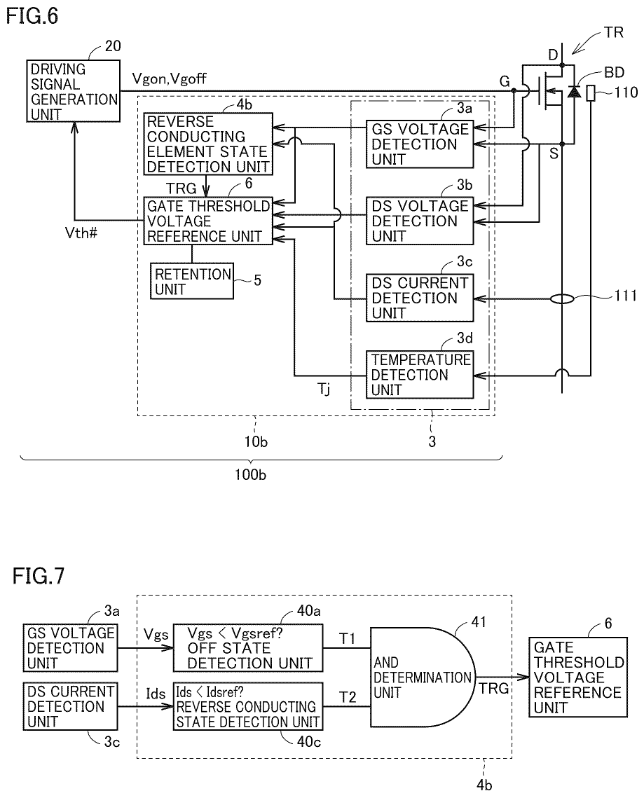

FIG. 6 shows a block diagram illustrating a configuration of a driving device 100b for a semiconductor element according to a second embodiment.

Driving device 100b for a semiconductor element according to the second embodiment differs from driving device 100a shown in FIG. 1 in that it includes a gate threshold voltage estimation unit 10b instead of gate threshold voltage estimation unit 10a (FIG. 1). Gate threshold voltage estimation unit 10b differs from gate threshold voltage estimation unit 10a in that it includes a reverse conducting element state detection unit 4b instead of reverse conducting element state detection unit 4a. The other configuration of driving device 100b is similar to driving device 100a according to the first embodiment and will not be further elaborated.

FIG. 7 shows a configuration example of reverse conducting element state detection unit 4b shown in FIG. 6.

Reverse conducting element state detection unit 4b differs from reverse conducting element state detection unit 4a in FIG. 4 in that it includes a reverse conducting state detection unit 40c instead of reverse conducting state detection unit 40b.

Reverse conducting state detection unit 40c compares drain-to-source current Ids detected by DS current detection unit 3c with a reverse conduction determination current Idsref set to a negative value and outputs a signal T2. When Ids<Idsref, reverse conducting state detection unit 40c determines that semiconductor element TR is in the reverse conducting state and sets T2=“1”. When not Ids<Idsref, it is determined that semiconductor element TR is not in the reverse conducting state, and T2=“0” is set. Reverse conduction determination current Idsref can be set to satisfy Idsref<0. Reverse conduction determination current Idsref corresponds to an example of “determination current”.

OFF state detection unit 40a outputs a signal T1 indicating a determination result as to whether semiconductor element TR is in the OFF state, based on the comparison between gate-to-source voltage Vgs detected by GS voltage detection unit 3a and OFF determination voltage Vgsref, in the same manner as described in the first embodiment. In the second embodiment, OFF determination voltage Vgsref corresponds to an example of “determination voltage”.

In other words, the second embodiment differs from the first embodiment only in that the reverse conducting state of semiconductor element TR (body diode BD) is determined using drain-to-source current Ids instead of drain-to-source voltage Vds.

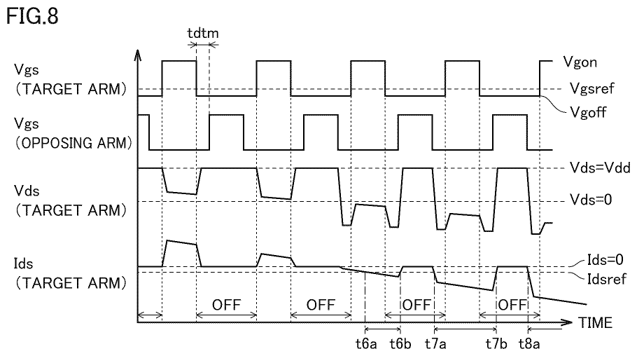

FIG. 8 shows a waveform diagram illustrating an operation example of the driving device for a semiconductor element according to the second embodiment. The behavior of voltage and current shown in FIG. 8 is similar to that in FIG. 5.

In the second embodiment, a period in which semiconductor element TR is off is determined in the same manner as in FIG. 5. On the other hand, the reverse conducting state of semiconductor element TR is determined in accordance with the comparison between drain-to-source current Ids and reverse conduction determination current Idsref.

As a result, in FIG. 8, trigger signal TRG shown in FIG. 7 is set to “1” in each of the periods of time t6a to t6b, t7a to t7b, and t7a to t7b, in which the OFF state of semiconductor element TR and the reverse conducting state of semiconductor element TR overlap. Gate threshold voltage reference unit 6 can calculate gate threshold voltage estimation value Vth # in the same manner as in the first embodiment, at each timing when trigger signal TRG changes from “0” to “1”.

In the configuration according to the present second embodiment, in addition to the effect described in the first embodiment, it is possible to determine the timing to estimate the gate threshold voltage using a detection value of drain-to-source current Ids which is less influenced by disturbance than a detection value of drain-to-source voltage Vds. This configuration can suppress estimation of the gate threshold voltage at a wrong timing by suppressing erroneous detection of the reverse conducting state of the reverse conducting element (body diode BD) and can improve the accuracy in estimating the gate threshold voltage.

### Third Embodiment

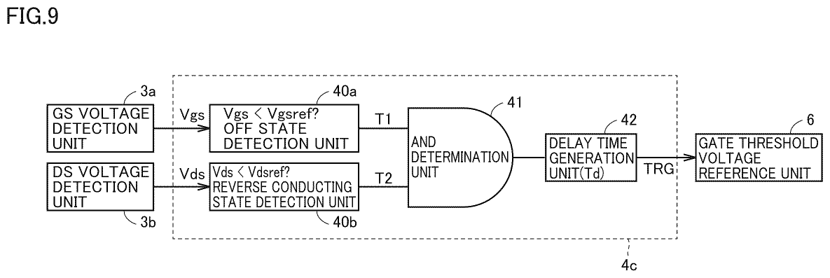

A third embodiment differs from the first embodiment in that reverse conducting element state detection unit 4a is replaced by a reverse conducting element state detection unit 4c shown in FIG. 9.

As shown in FIG. 9, reverse conducting element state detection unit 4c further includes a delay time generation unit 42 in addition to the configuration of reverse conducting element state detection unit 4a shown in FIG. 4. Delay time generation unit 42 provides a delay time Td between an output signal from AND determination unit 41 and trigger signal TRG. With this configuration, trigger signal TRG changes from “0” to “1” delay time Td later than the timing when an output signal from AND determination unit 41 changes from “0” to “1” (that is, the timing when both signals T1 and T2 from OFF state detection unit 40a and reverse conducting state detection unit 40b become “1”). With this configuration, compared with the first embodiment, gate threshold voltage reference unit 6 calculates gate threshold voltage estimation value Vth # based on the detection values of state detection unit 3 after delay time Td elapses.

Delay time Td is set to satisfy 0≤Td<tdtm for dead time tdtm (FIG. 5, FIG. 8) provided in the power conversion device containing semiconductor element TR. Further, it is preferable that delay time Td is set to satisfy tswst<Td<tdtm for the time required for switching tswt in the power conversion device. The time required for switching tswt is defined as a time required for drain-to-source voltage Vds to transition from Vdson+0.1·(Vdsoff−Vdson) to Vdson+0.9·(Vdsoff−Vdson) in a case where the ON/OFF state of one of the upper and lower arms of the power conversion device is switched and the drain-to-source voltage Vds of any semiconductor element transitions from a voltage in the ON state (Vdson) to a voltage in the OFF state (Vdsoff).

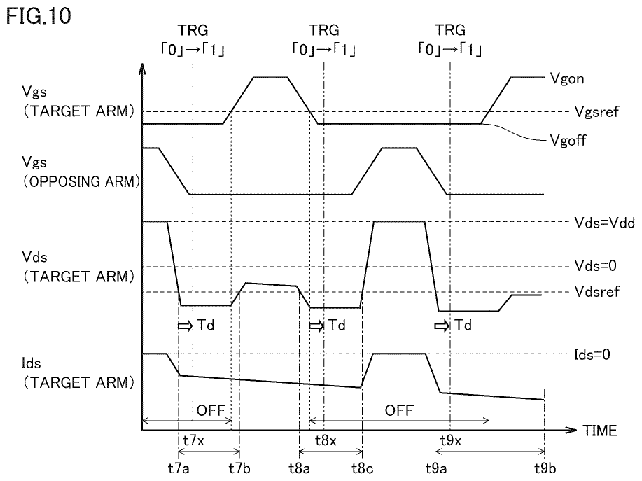

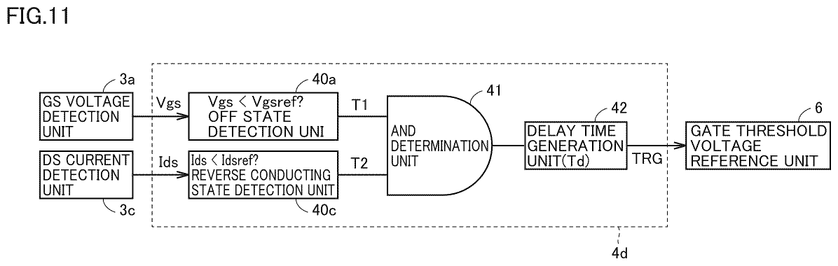

FIG. 10 shows a waveform diagram illustrating an operation example of the driving device for a semiconductor element according to the third embodiment.

In the operation example in FIG. 10, the OFF period of semiconductor element TR is determined based on the comparison between gate-to-source voltage Vgs and OFF determination voltage Vgsref, in the same manner as in the first embodiment, and in addition, the reverse conducting period of semiconductor element TR is determined based on the comparison between drain-to-source voltage Vds and reverse conduction determination voltage Vdsref.

With this configuration, in each of the periods of time t7a to t7b, t8a to t8b, and t9b to t9b, signal T2 output from reverse conducting state detection unit 40b is set to “1”, and at each of time t7a, t8a, and t9a, an output signal from AND determination unit 41 changes from “0” to “1”. However, because of the arrangement of delay time generation unit 42, the timing when trigger signal TRG changes from “0” to “1” is changed to time t7x, t8x, t9x, delay time Td later than t7a, t8a, t9b.

As a result, gate threshold voltage reference unit 6 can calculate gate threshold voltage estimation value Vth # in the same manner as in the first embodiment, using the detection values of state detection unit 3 at time t7x, t8x, t9x.

It is preferable that delay time generation unit 42 is configured to provide delay time Td for a rising edge at which an output signal from AND determination unit 41 changes from “0” to “1” and provide no delay time Td for a falling edge at which an output signal from AND determination unit 41 changes from “1” to “0”.

During switching of semiconductor element TR, that is, during on/off transition, the voltage and current detected by state detection unit 3 are in a transient state and therefore the detection values greatly change. Thus, during the switching, gate threshold voltage estimation value Vth # greatly changes for a minute deviation of timing, which may reduce the accuracy in estimating the gate threshold voltage.

On the other hand, in the configuration according to the third embodiment, delay time Td is provided, whereby gate threshold voltage reference unit 6 can calculate gate threshold voltage estimation value Vth # using the detection values of state detection unit 3 in a state in which the voltage and current of semiconductor element TR are stable. As a result, deterioration of the accuracy in estimating the gate threshold voltage as described above can be suppressed, Modification of Third Embodiment.

In a modification of the third embodiment, a configuration in which the delay time described in the third embodiment is provided for the configuration according to the second embodiment will be described.

The modification of the third embodiment differs from the second embodiment in that reverse conducting element state detection unit 4b is replaced by a reverse conducting element state detection unit 4d shown in FIG. 11.

As shown in FIG. 11, reverse conducting element state detection unit 4d further includes delay time generation unit 42 described in the third embodiment, in addition to the configuration of reverse conducting element state detection unit 4b shown in FIG. 7. Therefore, trigger signal TRG changes from “0” to “1” delay time Td later than the timing when an output signal from AND determination unit 41 changes from “0” to “1” (that is, the timing when both signals T1 and T2 from OFF state detection unit 40a and reverse conducting state detection unit 40c become “1”).

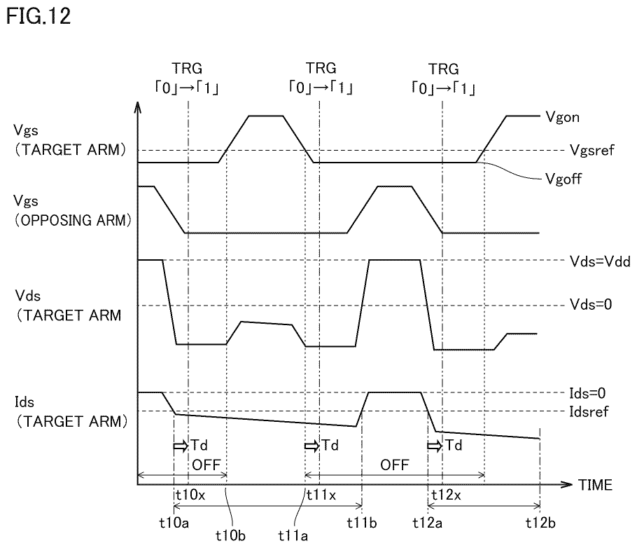

FIG. 12 shows a waveform diagram illustrating an operation example of the driving device for a semiconductor element according to the third embodiment.

In the operation example in FIG. 12, the OFF period of semiconductor element TR is determined based on the comparison between gate-to-source voltage Vgs and OFF determination voltage Vgsref, and in addition, the reverse conducting period of semiconductor element TR is determined based on the comparison between drain-to-source current Ids and reverse conduction determination current Idsref, in the same manner as in the second embodiment.

With this configuration, in each of the periods of time t10a to t11b and t12a to t12b, in which Ids<Idsref, signal T2 output from reverse conducting state detection unit 40b is set to “1”, and at each of time t10a, t11a, and t12a, an output signal from AND determination unit 41 changes from “0” to “1”. However, because of the arrangement of delay time generation unit 42, the timing when trigger signal TRG changes from “0” to “1” is changed to time t10x, t11x, t12x, delay time Td later than t10a, t11a, t12b.

As a result, gate threshold voltage reference unit 6 can calculate gate threshold voltage estimation value Vth # using the detection values of state detection unit 3 at time t10x, t11x, t12x while avoiding the time during switching in which the voltage and current of semiconductor element TR are unstable, in the same manner as in the third embodiment.

Thus, in the configuration according to the modification of the third embodiment, in addition to the effect described in the second embodiment, by providing delay time Td, it is possible to suppress deterioration of the accuracy in estimating the gate threshold voltage due to the use of the detection values of state detection unit 3 in a state in which the voltage and current of semiconductor element TR are unstable.

### Fourth Embodiment

In a fourth embodiment, control using gate threshold voltage estimation value Vth # calculated by gate threshold voltage reference unit 6 according to the first to third embodiments and the modification will be described.

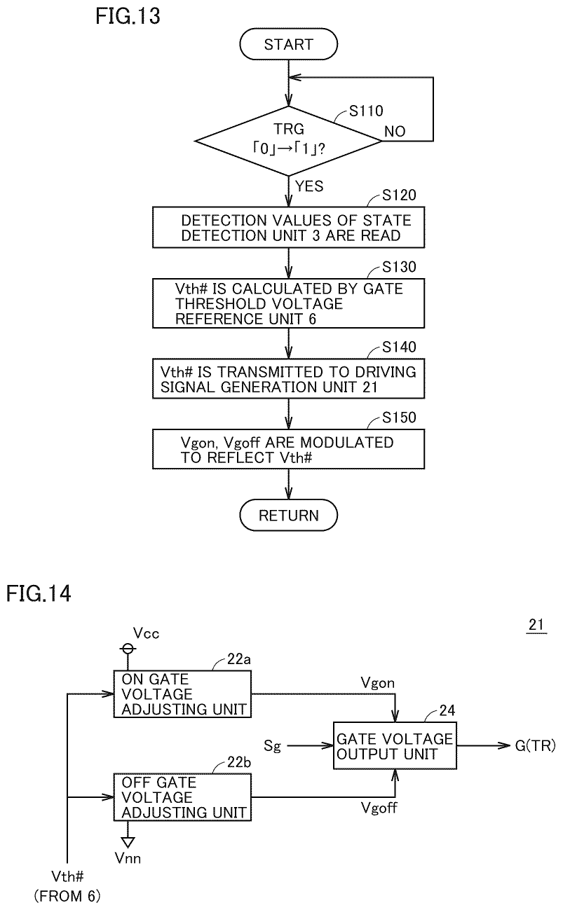

FIG. 13 shows a flowchart illustrating the operation of a driving device for a semiconductor element according to the fourth embodiment.

The driving device according to the fourth embodiment determines whether trigger signal TRG changes from “0” to “1” at step (hereinafter simply referred to as “S”) 110 and performs the process at S120 and subsequent steps at a timing when it changes from “0” to “1” (YES at S110).

The driving device according to the fourth embodiment reads a detection value of state detection unit 3 at a timing when trigger signal TRG changes from “0” to “1”, at S120, and calculates gate threshold voltage estimation value Vth # using the read detection value, at S130. The process at S110 to S130 is performed by gate threshold voltage estimation unit 10 according to any one of the first to third embodiments and the modification.

Further, at S140, the driving device according to the fourth embodiment transmits gate threshold voltage estimation value Vth # calculated at S130 to a driving signal generation unit 21 according to the fourth embodiment. Then, at S150, in driving signal generation unit 21, ON gate voltage Vgon and Vgoff to be output from driving signal generation unit 20 to gate G of semiconductor element TR are modulated so as to reflect the transmitted gate threshold voltage estimation value Vth #.

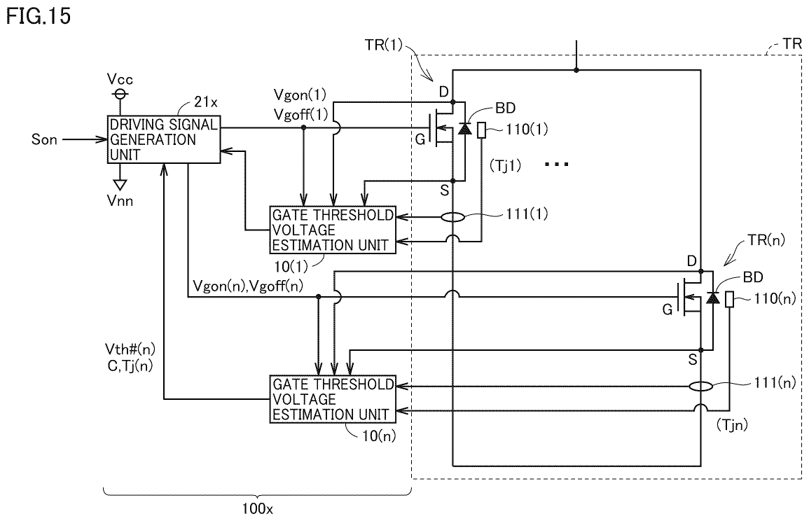

FIG. 14 shows a block diagram illustrating a configuration example of driving signal generation unit 21 according to the fourth embodiment.

Driving signal generation unit 21 includes an ON gate voltage adjusting unit 22a, an OFF gate voltage adjusting unit 22b, and a gate voltage output unit 24. ON gate voltage adjusting unit 22a generates ON gate voltage Vgon using a positive power supply voltage Vcc. Similarly, OFF gate voltage adjusting unit 22b generates OFF gate voltage Vgoff using a power supply voltage Vnn (Vnn<Vth).

Gate voltage output unit 24 outputs one of ON gate voltage Vgon and OFF gate voltage Vgoff to gate G of semiconductor element TR in accordance with gate signal Sg of semiconductor element TR. Specifically, in a period with gate signal Sg=“1” (ON instruction period), ON gate voltage Vgon is output, and in a period with gate signal Sg=“0” (OFF instruction period), OFF gate voltage Vgoff is output to gate G. In a dead time period, OFF gate voltage Vgoff is forcibly output.

ON gate voltage adjusting unit 22a and OFF gate voltage adjusting unit 22b have the function of variably adjusting ON gate voltage Vgon and OFF gate voltage Vgoff, respectively, in accordance with gate threshold voltage estimation value Vth # from gate threshold voltage reference unit 6.

For example, ON gate voltage Vgon and OFF gate voltage Vgoff can be set according to the following equation (1), using a reference ON gate voltage Vgon0 and a reference OFF gate voltage Vgoff0 at a predetermined gate threshold voltage reference value Vth0, gate threshold voltage estimation value Vth #, and a coefficient α (α>0).

Vgon=Vgon0+α·(Vth #−Vth0) (1)

Vgoff=Vgoff0+α·(Vth #−Vth0) (2)

Here, reference ON gate voltage Vgon0, reference OFF gate voltage Vgoff0, and coefficient α can be predetermined so as to achieve a desired characteristic, in consideration of power loss due to switching and energization of semiconductor element TR, and suppression of false turn-on, between which there is a trade-off. Alternatively, reference ON gate voltage Vgon0 can be set to be low, in favor of suppression of the characteristic deterioration of semiconductor element TR.

In the driving device for a semiconductor element according to the fourth embodiment, ON gate voltage Vgon and OFF gate voltage Vgoff can be modulated so as to reflect change of gate threshold voltage Vth such that a desired characteristic set at gate threshold voltage reference value Vth0 is maintained. This configuration can suppress increase of power loss or occurrence of false turn-on even when gate threshold voltage Vth of semiconductor element TR changes.

Driving signal generation unit 21 shown in FIG. 14 may also be implemented by a microcomputer in the same manner as the configuration example of gate threshold voltage estimation unit 10a illustrated in FIG. 2, or may be partially or entirely configured with a dedicated circuit such as FPGA and ASIC or an analog circuit. In other words, the functions of ON gate voltage adjusting unit 22a, OFF gate voltage adjusting unit 22b, and gate voltage output unit 24 can be implemented by at least one of software processing and hardware processing.

### Fifth Embodiment

In a fifth embodiment, a configuration of a driving device will be described, in which semiconductor element TR is configured with a plurality of semiconductor element units TR(1) to TR(n) connected in parallel.

FIG. 15 shows a block diagram illustrating a configuration of a driving device 100x for a semiconductor element according to the fifth embodiment. As shown in FIG. 15, semiconductor element TR described in the first to fourth embodiments is configured such that n (n is an integer of 2 or more) semiconductor element units TR(1) to TR(n) are connected in parallel. Such a configuration can ensure the current capacity of semiconductor element TR.

Driving device 100x according to the fifth embodiment turns on/off n (n is an integer of 2 or more) semiconductor element units TR(1) to TR(n) in accordance with gate signal Sg. Temperature detectors 110(1) to 110(n) and current detectors 111(1) to 111(n) are arranged for semiconductor element units TR(1) to TR(n), respectively.

Driving device 100x according to the fifth embodiment includes gate threshold voltage estimation units 10(1) to 10(n) arranged corresponding to semiconductor element units TR(1) to TR(n), respectively, and a driving signal generation unit 21x.

Any one of the configurations described in the first to third embodiments and the modification can be applied to each of gate threshold voltage estimation units 10(1) to 10(n). Each of gate threshold voltage estimation units 10(1) to 10(n) calculates gate threshold voltage estimation value Vth # for the corresponding one of semiconductor element units TR(1) to TR(n) when the OFF state and the reverse conducting state of semiconductor element units TR(1) to TR(n) are detected as described above.

Driving signal generation unit 21x receives gate threshold voltage estimation values Vth #(1) to Vth #(n) from gate threshold voltage estimation units 10(1) to 10(n). Further, driving signal generation unit 21x separately sets ON gate voltages Vgon(1) to Vgon(n) and OFF gate voltages Vgoff(1) to Vgoff(n) for semiconductor element units TR(1) to TR(n). For example, driving signal generation unit 21x has n sets of the configuration of driving signal generation unit 21 shown in FIG. 14 in parallel corresponding to semiconductor element units TR(1) to TR(n).

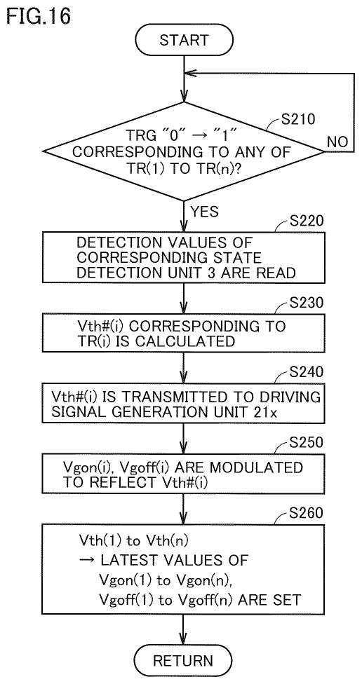

FIG. 16 shows a flowchart illustrating the operation of the driving device for a semiconductor element according to the fifth embodiment.

Driving device 100x according to the fourth embodiment determines whether trigger signal TRG changes from “0” to “1” in any of gate threshold voltage estimation units 10(1) to 10(n), at S210, and performs the process at S220 and subsequent steps when trigger signal TRG changes from “0” to “1” (YES at S110) corresponding to any of semiconductor element units TR(1) to TR(n). Hereinafter, the operation performed when trigger signal TRG changes from “0” to “1” in a semiconductor element unit TR(i) (i is an integer of 1≤i≤n) among semiconductor element units TR(1) to TR(n) will be described.

Driving device 100x reads a detection value of state detection unit 3 corresponding to semiconductor element unit TR(i) at a timing when trigger signal TRG changes from “0” to “1”, at S220, and calculates a gate threshold voltage estimation value Vth #(i) of semiconductor element unit TR(i) using the read detection value, at S230. The process at S210 to S230 is performed by any of gate threshold voltage estimation units 10(1) to 10(n) in FIG. 15.

Further, at S240, driving device 100x transmits gate threshold voltage estimation value Vth # calculated at S230 to driving signal generation unit 21x. Then, at S250, in driving signal generation unit 21x, ON gate voltage Vgon(i) and Vgoff(i) of semiconductor element unit TR(i) are modulated so as to reflect gate threshold voltage estimation value Vth #(i) transmitted at S240.

ON gate voltage Vgon(i) and Vgoff(i) are modulated such that the difference between ON gate voltage Vgon and gate threshold voltage Vth (Vgon-Vth) and the difference between OFF gate voltage Vgoff and gate threshold voltage Vth (Vth-Vgoff) are balanced among semiconductor element units TR(1) to TR(n).

For example, ON gate voltage Vgon(i) and Vgoff(i) can be calculated according the following equations (3) and (4) obtained by expanding the above equations (1) and (2) for each of semiconductor element units TR(1) to TR(n).

Vgon(i)=Vgon0+α·(Vth(i) #−Vth0) (3)

Vgoff(i)=Vgoff0+α·(Vth(i) #−Vth0) (4)

Reference ON gate voltage Vgon0, reference OFF gate voltage Vgoff0, coefficient α, and gate threshold voltage reference value Vth0 similar to those in equations (1) and (2) can be defined such that a desired characteristic can be obtained at gate threshold voltage reference value Vth0. In the above equations (3) and (4), these values are common to semiconductor element units TR(1) to TR(n), but these values may be set separately for each of semiconductor element units TR(1) to TR(n).

At S260, driving device 100x sets the latest values of ON gate voltages Vgon(1) to Vgon(n) and OFF gate voltages Vgoff(1) to Vgoff(n) of semiconductor element units TR(1) to TR(n) so as to reflect the modulation of ON gate voltage Vgon(i) and Vgoff(i) at S250.

In the driving device for a semiconductor element according to the fifth embodiment, the operation of semiconductor elements can be equalized even when the gate threshold voltages differ among a plurality of semiconductor element units TR(1) to TR(n) connected in parallel. This configuration can reduce current variations during switching and on/off among the semiconductor elements, thereby suppressing variations of operating temperature due to difference in the amount of generated heat, and occurrence of oscillation phenomenon.

In particular, by using equations (3) and (4), it is possible to modulate ON gate voltage Vgon and OFF gate voltage Vgoff so as to reflect change of gate threshold voltage Vth, for each of semiconductor element units TR(1) to TR(n), such that a desired characteristic set at gate threshold voltage reference value Vth0 is maintained.

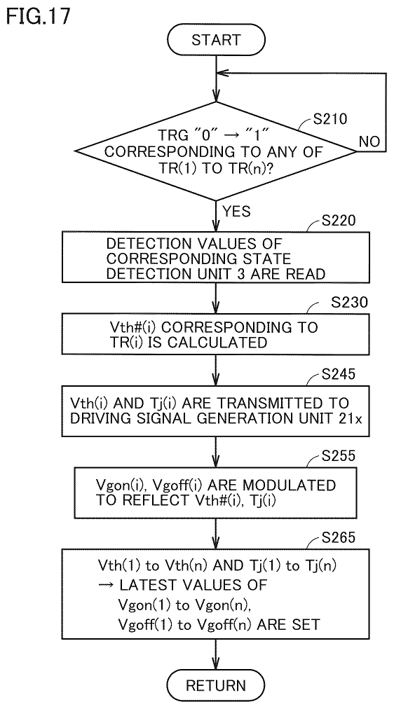

FIG. 17 shows a flowchart illustrating a modification of the operation of the driving device for a semiconductor element according to the fifth embodiment.

Driving device 100x can perform S245, S255, and S265 instead of S240, S250, and S260 in FIG. 16.

Driving device 100x calculates gate threshold voltage estimation value Vth #(i) of semiconductor element unit TR(i) at S230 in the same manner as in FIGS. 16, and transmits gate threshold voltage estimation value Vth #(i) as well as operating temperature Tj(i) of semiconductor element unit TR(i) to driving signal generation unit 21x, at S245.

At S255, driving device 100x modulates ON gate voltage Vgon(i) and Vgoff(i) of semiconductor element unit TR(i) so as to reflect gate threshold voltage estimation value Vth #(i) and operating temperature Tj(i) transmitted at S245. The modulation in accordance with operating temperature Tj is performed such that the difference of operating temperatures Tj(1) to Tj(n) is reduced among semiconductor element units TR(1) to TR(n).

For example, ON gate voltage Vgon(i) and Vgoff(i) can be calculated according the following equations (5) and (6).

Vgon(i)=Vgon0+α·ΔVth(i)+β·ΔTj(i) (5)

Vgoff(i)=Vgoff0+α·ΔVth(i)+β·ΔTj(i) (6)
where ΔVth(i)=Vth(i) #−Vth0, ΔTj(i)=Tj (i)−Tj0.

Equations (5) and (6) are obtained by adding the term β·(Tj(i)−Tj0) using a coefficient β (β<0) to equations (3) and (4). With this configuration, in order to suppress the amount of generated heat in the semiconductor element unit with rising operating temperature, ON gate voltage Vgon(i) and Vgoff(i) are lowered in proportion to the amount of rise of operating temperature Tj (i) from a predetermined reference temperature Tj0.

Coefficient β and reference temperature Tj0 are also common to semiconductor element TR units (1) to TR(n) in equations (5) and (6) but may be set separately for each of semiconductor element units TR(1) to TR(n).

At S265, driving device 100x sets the latest values of ON gate voltages Vgon(1) to Vgon(n) and OFF gate voltages Vgoff(1) to Vgoff(n) of semiconductor element units TR(1) to TR(n) so as to reflect the modulation of ON gate voltage Vgon(i) and Vgoff(i) at S255.

In the modification shown in FIG. 17, variations of operating temperatures Tj(1) to Tj(n) of semiconductor element units TR(1) to TR(n) can be further suppressed in the driving device for a semiconductor element according to the fifth embodiment.

In the first to fifth embodiments, an example in which semiconductor element TR is a field-effect transistor (MOSFET) has been described. However, semiconductor element TR may be composed of a reverse conductive (RC)-IGBT containing a reverse conducting element. In this case, “drain” and “source” read as “collector (first electrode)” and “emitter (second electrode)” whereby the gate threshold voltage can be estimated using similar current and voltage of semiconductor element TR composed of IGBT.

### Sixth Embodiment

In the present embodiment, the driving device for a semiconductor element according to the foregoing first to fifth embodiments is applied to a power conversion device. The present disclosure is not limited to a particular power conversion device, but a case where the present disclosure is applied to a three-phase inverter will be described as a sixth embodiment.

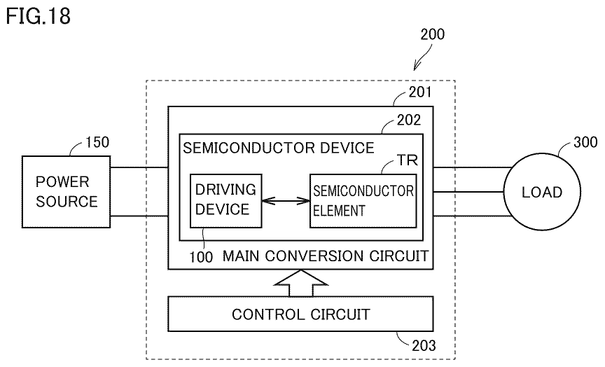

FIG. 18 is a block diagram showing a configuration of a power conversion system to which a power conversion device is applied according to the present embodiment.

The power conversion system shown in FIG. 18 includes a power source 150, a power conversion device 200, and a load 300. Power source 150 is a DC power source and supplies a DC power to power conversion device 200. Power source 150 can be of a variety of kinds and, for example, can be configured with a DC system, a solar battery, or a storage battery. Alternatively, power source 150 can be configured with a rectifying circuit connected to an AC system or an AC/DC converter. Alternatively, power source 150 can be configured with a DC/DC converter converting a DC power output from a DC system into a predetermined power.

Power conversion device 200 is typically a three-phase inverter connected between power source 150 and load 300 and converts a DC power supplied from power source 150 into an AC power to supply the AC power to load 300. As shown in FIG. 18, power conversion device 200 includes a main conversion circuit 201 to convert a DC power into an AC power and output the AC power and a control circuit 203 to output a control signal for controlling main conversion circuit 201 to main conversion circuit 201.

Load 300 is a three-phase motor driven by the AC power supplied from power conversion device 200. Load 300 is not limited to a specific application and includes motors installed in a variety of electric devices. For example, load 300 can be configured with a motor for hybrid vehicles, electric vehicles, railway vehicles, elevators, and air conditioners.

The detail of power conversion device 200 will be described below.

Main conversion circuit 201 controls the on/off of a semiconductor switching element with a freewheeling diode (reverse conducting element) in accordance with gate signal Sg (for example, in FIG. 1) supplied from control circuit 203 to perform DC/AC power conversion between power source 150 and load 300. There are various kinds of specific circuit configuration of main conversion circuit 201. For example, main conversion circuit 201 can be a two-level three-phase full-bridge circuit including six semiconductor switching elements and freewheeling diodes. In other words, six semiconductor switching elements are connected two by two in series to form upper and lower arms, and the upper and lower arms constitute each phase of the full-bridge circuit (U phase, V phase, and W phase). The output terminals of the upper and lower arms, that is, three output terminals of main conversion circuit 201 are connected to load 300.

At least one of the semiconductor switching elements (including the freewheeling diodes) of main conversion circuit 201 is configured with semiconductor element TR controlled on/off by driving device 100. Driving device 100 collectively refers to the driving devices according to the foregoing first to fifth embodiments. In other words, main conversion circuit 201 includes at least one semiconductor device 202 including semiconductor element TR having a reverse conducting element as a freewheeling diode and driving device 100 according to the first to fifth embodiments to turn on/off the semiconductor element TR.

Embodiments disclosed here should be understood as being illustrative rather than being limitative in all respects. The technical scope of the present disclosure is shown not in the foregoing description but in the claims, and it is intended that all modifications that come within the meaning and range of equivalence to the claims are embraced here.

### REFERENCE SIGNS LIST

3 state detection unit, 3a GS voltage detection unit, 3b DS voltage detection unit, 3c DS current detection unit, 3d temperature detection unit, 4, 4a, 4b, 4c, 4d reverse conducting element state detection unit, 5 retention unit, 6 gate threshold voltage reference unit, 10, 10a, 10b gate threshold voltage estimation unit, 12 memory, 13 I/O interface, 15 bus, 20, 21, 21x driving signal generation unit, 22a ON gate voltage adjusting unit, 22b OFF gate voltage adjusting unit, 24 gate voltage output unit, 40a OFF state detection unit, 40b, 40c reverse conducting state detection unit, 41 determination unit, 42 delay time generation unit, 100, 100a, 100b, 100x driving device, 110 temperature detector, 111 current detector, 150 power source, 200 power conversion device, 201 main conversion circuit, 202 semiconductor device, 203 control circuit, 300 load, BD body diode, Ids drain-to-source current, Idsref reverse conduction determination current, Sg gate signal, TR semiconductor element, TR(1) to TR(n) semiconductor element unit, TRG trigger signal, Tj operating temperature, Vdc drain-to-source voltage, Vdsref reverse conduction determination voltage, Vgoff OFF gate voltage, Vgon ON gate voltage, Vgs gate-to-source voltage, Vgsref OFF determination voltage, Vth # gate threshold voltage estimation value, Td delay time, tdtm dead time, tswt time required for switching.

1. A driving device for a semiconductor element having an insulated gate structure,
the semiconductor element being configured such that current is produced from a first electrode to a second electrode in an ON state, the semiconductor element containing a reverse conducting element for ensuring a current path from the second electrode to the first electrode,
the driving device comprising:
driving signal generation circuitry to output one of an ON gate voltage for turning on the semiconductor element and an OFF gate voltage for turning off the semiconductor element to a gate of the semiconductor element; and
gate threshold voltage estimation circuitry to calculate an estimation value of a gate threshold voltage of the semiconductor element, based on state information of the semiconductor element acquired when the semiconductor element is in an OFF state and in a reverse conducting state in which the reverse conducting element is energized.

2. The driving device for a semiconductor element according to claim 1, wherein the gate threshold voltage estimation circuitry calculates an estimation value of the gate threshold voltage from the acquired state information, using correspondence information between the state information and the gate threshold voltage that is defined in advance in accordance with a current voltage characteristic of the semiconductor element when the semiconductor element is in the OFF state and the reverse conducting state.

3. The driving device for a semiconductor element according to claim 1, wherein the state information includes a first current flowing between the first and second electrodes, a first voltage that is a voltage difference of the gate with respect to the second electrode, a second voltage that is a voltage difference of the first electrode with respect to the second electrode, and an operating temperature of the semiconductor element.

4. The driving device for a semiconductor element according to claim 1, wherein
the gate threshold voltage estimation circuitry includes
state detection circuitry to detect, as the state information, a first current flowing between the first and second electrodes, a first voltage that is a voltage difference of the gate with respect to the second electrode, a second voltage that is a voltage difference of the first electrode with respect to the second electrode, and an operating temperature of the semiconductor element,
retention circuitry to store correspondence information of the first voltage, the second voltage, the first current, and the operating temperature with the gate threshold voltage, the correspondence information being defined in advance in accordance with a current voltage characteristic of the semiconductor element when the semiconductor element is in the OFF state and the reverse conducting state,
reverse conducting element state detection circuitry to detect that the semiconductor element is in the OFF state and the reverse conducting state, and
gate threshold voltage reference circuitry to calculate an estimation value of the gate threshold voltage by referring to the correspondence information stored in the retention circuitry using a detection value of the state information by the state detection circuitry when the reverse conducting element state detection circuitry is detecting that the semiconductor element is in the OFF state and the reverse conducting state.

5. The driving device for a semiconductor element according to claim 4, wherein
the reverse conducting element state detection circuitry detects the OFF state when the first voltage is lower than a first determination voltage, and detects the reverse conducting state of the semiconductor element when the second voltage is lower than a second determination voltage,
the first determination voltage is set to be higher than the OFF gate voltage, and
the second determination voltage is a negative voltage.

6. The driving device for a semiconductor element according to claim 4, wherein
the first current is defined such that current flowing from the first electrode to the second electrode is a positive current,
the reverse conducting element state detection circuitry detects the OFF state when the first voltage is lower than a determination voltage, and detects the reverse conducting state of the semiconductor element when the first current is lower than a determination current,
the determination voltage is set to be higher than the OFF gate voltage, and
the determination current is a negative current.

7. The driving device for a semiconductor element according to claim 4, wherein the gate threshold voltage reference circuitry calculates an estimation value of the gate threshold voltage, using a detection value of the state information by the state detection circuitry at a point of time when a predetermined delay time elapses since the reverse conducting element state detection circuitry detects that the semiconductor element is in the OFF state and the reverse conducting state.

8. The driving device for a semiconductor element according to claim 1, wherein
the driving signal generation circuitry includes
voltage adjusting circuitry to modulate the ON gate voltage and the OFF gate voltage from a predetermined ON gate reference voltage and OFF gate reference voltage, in accordance with an estimation value of the gate threshold voltage calculated by the gate threshold voltage estimation circuitry.

9. The driving device for a semiconductor element according to claim 8, wherein
the voltage adjusting circuitry modulates the ON gate voltage and the OFF gate voltage, in accordance with a difference of the estimation value with respect to a predetermined reference value of the gate threshold voltage, such that the ON gate voltage and the OFF gate voltage are higher than the ON gate reference voltage and the OFF gate reference voltage when the estimation value is higher than the reference value, and the ON gate voltage and the OFF gate voltage are lower than the ON gate reference voltage and the OFF gate reference voltage when the estimation value is lower than the reference value.

10. The driving device according to claim 1, wherein
the semiconductor element is configured with a plurality of semiconductor element units connected in parallel,
each of the semiconductor element units is configured similar to the semiconductor element such that current is produced from the first electrode to the second electrode in the ON state, and contains the reverse conducting element for ensuring a current path from the second electrode to the first electrode,
the gate threshold voltage estimation circuitry calculates an estimation value of the gate threshold voltage for each of the semiconductor element units,
the driving signal generation circuitry outputs the ON gate voltage or the OFF gate voltage set for each of the semiconductor element units to respective gates of the semiconductor element units such that the semiconductor element units are controlled on/off in common, and
the driving signal generation circuitry includes
a voltage adjusting circuitry to modulate the respective ON gate voltages and OFF gate voltages of the semiconductor element units, in accordance with the estimation value calculated corresponding to each of the semiconductor element units, such that a difference between the ON gate voltage and the estimation value and a difference between the OFF gate voltage and the estimation value are balanced among the semiconductor element units.

11. The driving device for a semiconductor element according to claim 10, wherein
the voltage adjusting circuitry modulates the ON gate voltage and the OFF gate voltage of each of the semiconductor element units, in accordance with a difference of the estimation value with respect to a predetermined reference value of the gate threshold voltage in the semiconductor element unit, such that the ON gate voltage and the OFF gate voltage are higher than a predetermined ON gate reference voltage and OFF gate reference voltage when the estimation value is higher than the reference value, and the ON gate voltage and the OFF gate voltage are lower than the ON gate reference voltage and the OFF gate reference voltage when the estimation value is lower than the reference value.

12. The driving device for a semiconductor element according to claim 10, wherein the voltage adjusting circuitry further modulates the ON gate voltage and the OFF gate voltage of each of the semiconductor element units, in accordance with an operating temperature of the semiconductor element unit, such that a difference of operating temperature decreases among the semiconductor element units.

13. The driving device for a semiconductor element according to claim 12, wherein
the voltage adjusting circuitry modulates the ON gate voltage and the OFF gate voltage of each of the semiconductor element units, in accordance with a difference of a detection value of the operating temperature with respect to a reference temperature value in the semiconductor element unit, such that the ON gate voltage and the OFF gate voltage decrease when the detection value is higher than the reference temperature value, and the ON gate voltage and the OFF gate voltage increase when the detection value is lower than the reference temperature value.

14. A power conversion device comprising:
main conversion circuitry including at least one semiconductor element controlled on/off by the driving device for a semiconductor element according to claim 1, the main conversion circuitry converting an input power and outputting the converted power; and
control circuitry to output a control signal for controlling the main conversion circuitry to the main conversion circuitry.
